(19) United States
(12) Patent Application Publication
(10) Pub. No.: US 2007/0077720 A1
(43) Pub. Date: Apr. 5, 2007

(54) Manufacturing method for an integrated semiconductor structure and corresponding integrated semiconductor structure

(75) Inventors: Lars Heineck, Dresden (DE); Marco Lepper, Dresden (DE)

Correspondence Address: MORRISON & FOERSTER LLP, 1650 TYSONS BOULEVARD, SUITE 300, MCLEAN, VA, 22102, US

(73) Assignee: INFINEON TECHNOLOGIES AG, Munchen (DE)

(21) Appl. No.: 11/242,140

(22) Filed: Oct. 4, 2005

(51) Int. Cl. H01L 21/331

(52) U.S. Cl. 438/372

(57) ABSTRACT

The present invention provides a manufacturing method for an integrated semiconductor structure and a corresponding integrated semiconductor structure. The manufacturing method comprises the steps of: providing an integrated circuit substrate having a main surface; providing a dielectric layer on said main surface; providing a via in said dielectric layer, said via exposing a contact area of said integrated circuit substrate; depositing a first liner of Ti on said dielectric layer and said contact area; performing an annealing process such that a Ti silicide region is formed in said contact area from a part of said first liner of Ti and a remaining part of said first liner of Ti is converted into a TiN liner; selectively removing said converted remaining part with respect to said Ti silicide region and said dielectric layer; depositing a second liner of TiN on said dielectric layer and said contact area; and depositing a conductive layer on said second liner of TiN which conductive layer forms a contact in said via and a wiring layer above and in a periphery of said via.

### BACKGROUND OF THE INVENTION

1. Field of the Invention

The present invention relates to a manufacturing method for an integrated semiconductor structure and to a corresponding integrated semiconductor structure.

2. Description of the Related Art

Although in principle applicable to arbitrary integrated semiconductor structures, the following invention and the underlying problems will be explained with respect to integrated memory circuits in silicon technology.

FIG. 2A-E show schematic cross-sections of a manufacturing method for an integrated semiconductor structure as an example of the underlying problems of the present invention.

In integrated semiconductor circuit structures, contacts in dielectric layers are necessary for connecting the semiconductor circuit layer with a wiring layer or for connecting adjacent wiring layers.

In FIG. 2A, reference sign 1, denotes an integrated circuit substrate including (not shown) integrated circuits. A dielectric layer 2 of Boron-Phosphorus-Silicate-Glass is provided above said integrated circuit substrate 1 which dielectric layer 2 has a via 3 that exposes a contact area 1a of said integrated circuit substrate 1.

Above this structure, a Ti/TiN/Ti liner 4 is deposited in an over-conformal PVD deposition step (PVD=Physical Vapour Deposition). Over-conformal means that a thickness of said Ti/TiN/Ti liner 4 decreases on the side wall of said via 3 with increasing depth as graphically illustrated in FIG. 2A.

With reference to FIG. 2B, an annealing step in N₂ atmosphere is performed in order to provide a Ti silicide region 5 in said contact area 1a of said integrated circuit substrate. In said annealing step, a part of said Ti/TiN/Ti liner 4 is diffused into said integrated semiconductor substrate.

Next, as shown in FIG. 2C, a PVD deposition step is performed for depositing a tungsten layer on the resulting structure which tungsten layer 6 fills said via 3 and covers the Ti/TiN/Ti liner 4 in the periphery of said via 3.

In a following process step which is illustrated in FIG. 2D, a CMP step (CMP=Chemical Mechanical Polishing) is performed for removing said tungsten layer 6 from the upper surface of said dielectric layer 2.

Finally, a wiring layer 7 made of aluminium is deposited and structured on the resulting structure which wiring layer 7 is in electrical contact with the contact fill 6 in said via 3 and therefore with the contact area 1a of said integrated circuit substrate 1.

In this manufacturing process, it is a problem that the Ti/TiN/Ti liner 4 causes a high thickness of the layer above the dielectric layer 2 which is the sum of the thicknesses of the Ti/TiN/Ti liner 4 and the wiring layer 7.

Another disadvantage of the known process is the overhang which forms on the upper side of the via 3 and which makes it difficult to fill the via 3 when the diameter of said via 3 is further diminished.

### SUMMARY OF THE INVENTION

Therefore, it is an object of the present invention to provide an improved manufacturing method for an integrated semiconductor contact structure which allows a more compact arrangement.

The object is achieved in accordance with the invention by means of a manufacturing method for an integrated semiconductor structure comprising the steps of: providing an integrated circuit substrate having a main surface; providing a dielectric layer on said main surface; providing a via in said dielectric layer, said via exposing a contact area of said integrated circuit substrate; depositing a first liner of Ti on said dielectric layer and said contact area; performing an annealing process such that a Ti silicide region is formed in said contact area from a part of said first liner of Ti and a remaining part of said first liner of Ti is converted into a TiN liner; selectively removing said converted remaining part with respect to said Ti silicide region and said dielectric layer; depositing a second liner of TiN on said dielectric layer and said contact area; and depositing a conductive layer on said second liner of TiN which conductive layer forms a contact in said via and a wiring layer above and in a periphery of said via.

A particular advantage is an improvement of the aspect ratio for the contact fill, a reduction of the thickness of the wiring layers stack and a simpler manufacture of the wiring layer.

In a restricted version of the invention the method further comprises the step of structuring said wiring layer.

In another restricted version of the invention said conductive layer is a Tungsten layer.

In another restricted version of the invention said first liner of Ti is deposited in an overconformal deposition step.

In another restricted version of the invention said converted remaining part of said first liner of Ti is selectively removed in a wet etching step.

In another restricted version of the invention said first liner of Ti has a thickness of 30 to 70 nm and said second liner of TiN has a thickness of 5 to 15 nm.

### DESCRIPTION OF THE DRAWINGS

In the Figures:

FIG. 1A-F show schematic cross-sections of a manufacturing method for an integrated semiconductor structure as an embodiment of the present invention; and

FIG. 2A-E show schematic cross-sections of a manufacturing method for an integrated semiconductor structure as an example of the underlying problems of the present invention.

In the Figures, identical reference signs denote equivalent or functionally equivalent components.

### DESCRIPTION OF THE PREFERRED EMBODIMENTS

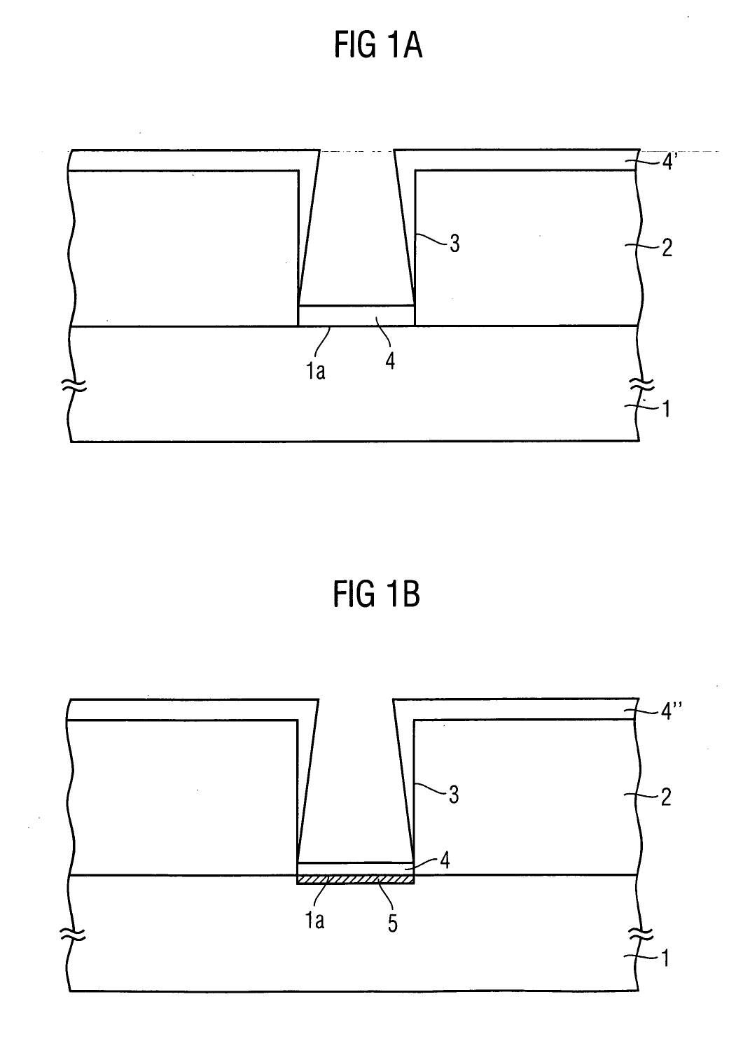

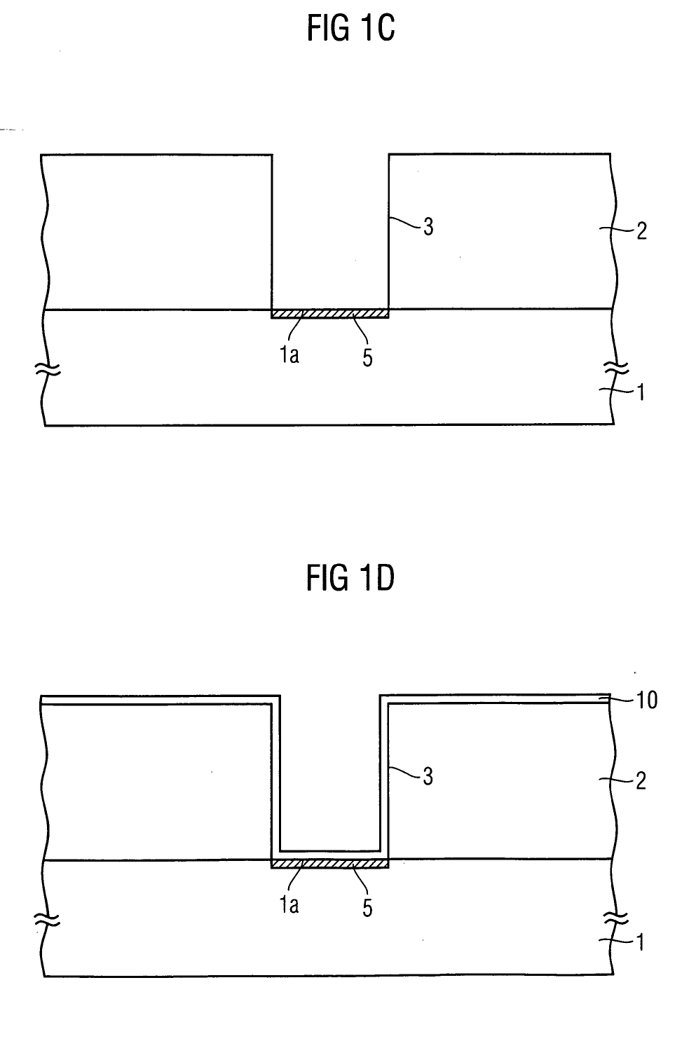

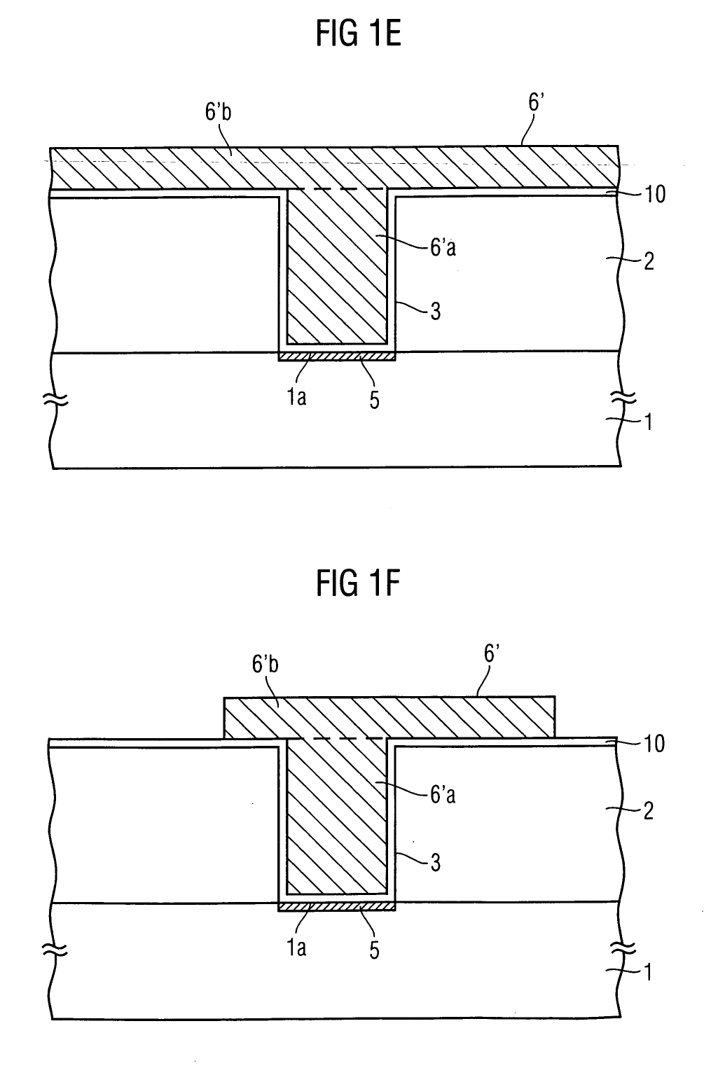

FIG. 1A-F show schematic cross-sections of a manufacturing method for an integrated semiconductor structure as an embodiment of the present invention.

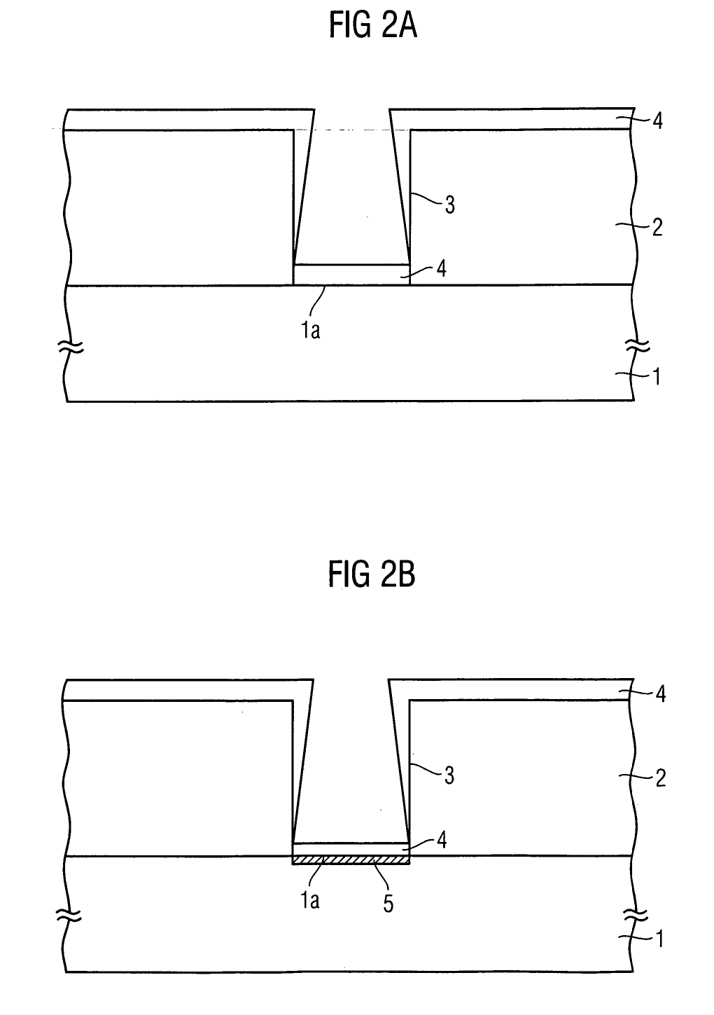

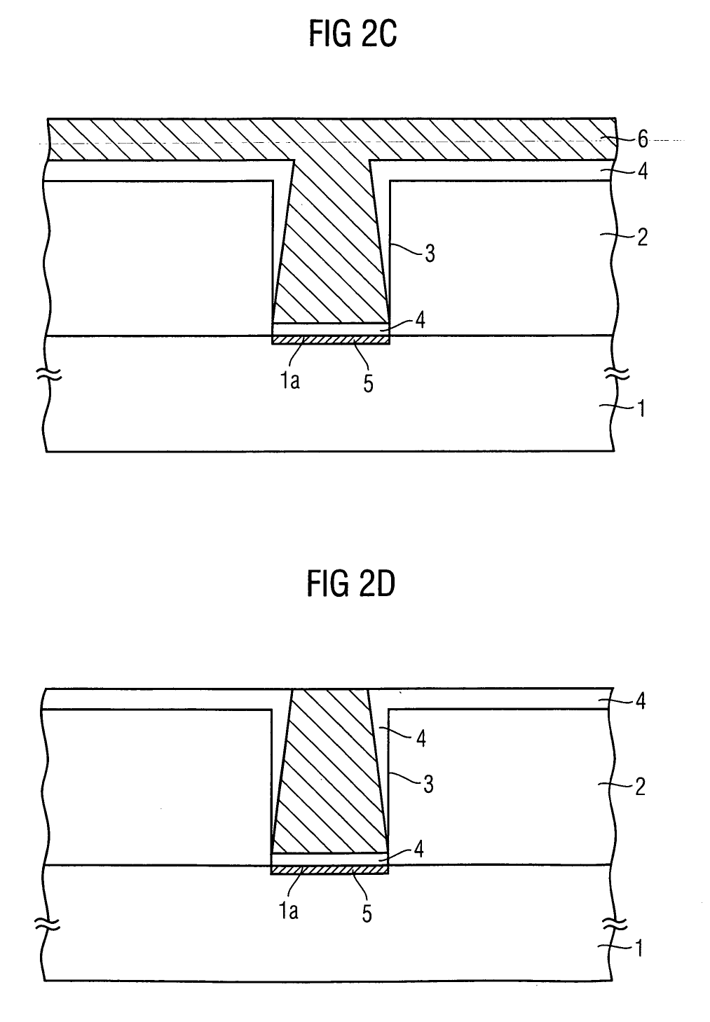

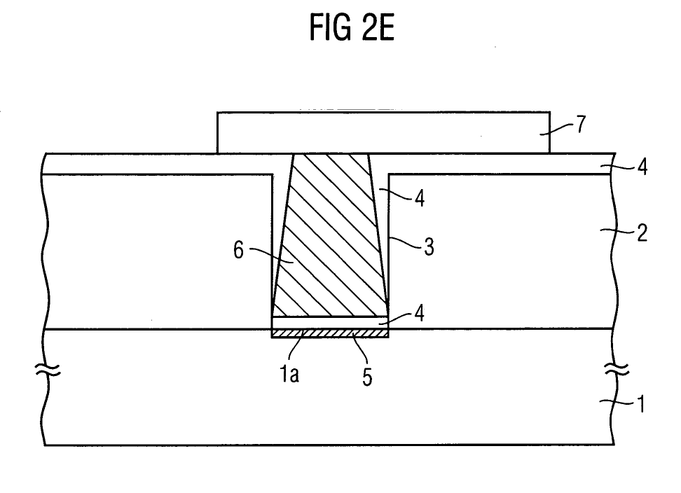

In FIG. 2A, reference sign 1, denotes an integrated circuit substrate including (not shown) integrated circuits. A dielectric layer 2 of Boron-Phosphorus-Silicate-Glass is provided above said integrated circuit substrate 1 which dielectric layer 2 has a via 3 that exposes a contact area 1a of said integrated circuit substrate 1.

Above this structure, a Ti liner 4′ having a thickness of 50 nm is deposited in an over-conformal PVD deposition step (PVD=Physical Vapour Deposition). Over-conformal means that a thickness of said Ti liner 4′ decreases on the side wall of said via 3 with increasing depth as graphically illustrated in FIG. 1A.

With reference to FIG. 1B, an annealing step in N₂ atmosphere is performed in order to provide a Ti silicide region 5 in said contact area 1a of said integrated circuit substrate. In said annealing step, a part of said Ti liner 4′ is diffused into said integrated semiconductor substrate 1. Moreover, the remaining part of the liner 4 is converted into a TiN liner 4″.

With reference to FIG. 1C, the remaining TiN liner 4″ of said converted first liner 4′ is selectively removed in a wet etching step which exposes said dielectric layer 2 and said Ti-silicide region 5 in said contact area 1a of said integrated circuit substrate 1.

With reference to FIG. 1D, a second liner 10 is deposited over the resulting structure which second liner 10 of TiN has a thickness of 5 to 15 nm, preferably 10 nm, which is much less than the thickness of said first liner 4′ of Ti. This second liner 10 of TiN is deposited in a MOCVD deposition step.

The TiN liner 10 is necessary, because the tungsten is deposited in a following WF₆ CVD step, and WF₆ would attack or react with underlying materials.

Next, as shown in FIG. 1E, a tungsten layer 6′ is deposited over the resulting structure and forms a contact 6′a in said via 3 and a wiring layer 6′b above and in a periphery of said via 3.

In a next process step which is shown in FIG. 1F, the wiring layer 6′b and the underlying second liner 10 of TiN are structured in a lithography step.

Thus, the manufacturing method of this embodiment allows to reduce the layers above the dielectric layer 2 which is a sum of the thicknesses of the second liner 10 and the wiring liner 6′b. Moreover, in this process, the contact fill and the wiring layer are combined in a single layer and a single manufacturing step.

Although modifications and changes may be suggested by those skilled in the art, it is the intention of the inventors to embody within the patent warranted heron all changes and modifications as reasonably and properly come within the scope of their contribution to the art.

Particularly, the selection of the materials is only an example and can be varied variously.

### LIST OF REFERENCE SIGNS

1 substrate
1a contact area
2 dielectric layer
3 via
4 Ti/TiN/Ti liner
4′ Ti liner
4″ TiN liner
5 Ti silicide region
6′ conductive W layer
6′a contact
6′b wiring layer
7 wiring layer
10 TiN liner

1. A manufacturing method for an integrated semiconductor structure comprising the steps of:
providing an integrated circuit substrate (1) having a main surface;
providing a dielectric layer (2) on said main surface;
providing a via (3) in said dielectric layer (2), said via (3) exposing a contact area (1a) of said integrated circuit substrate (1);
depositing a first liner (4′) of Ti on said dielectric layer (2) and said contact area (1a);
performing an annealing process such that a Ti silicide region (5) is formed in said contact area (1a) from a part of said first liner (4′) of Ti and a remaining part of said first liner (4′) of Ti is converted into a TiN liner (4″);
selectively removing said converted remaining part with respect to said Ti silicide region (1a) and said dielectric layer (2);
depositing a second liner (10) of TiN on said dielectric layer (2) and said contact area (1a); and
depositing a conductive layer (6′) on said second liner (10) of TiN which conductive layer (6′) forms a contact (6′a) in said via (3) and a wiring layer (6′b) above and in a periphery of said via (3).

2. The method according to claim 1, further comprising the step of structuring said wiring layer (6′b).

3. The method according to claim 1, wherein said conductive layer (6′) is a Tungsten layer.

4. The method according to claim 1, wherein said first liner (4) of Ti is deposited in an overconformal deposition step.

5. The method according to claim 1,
wherein said converted remaining part of said first liner (4) of Ti is selectively removed in a wet etching-step.

6. The method according to claim 1,
wherein said first liner (4) of Ti has a thickness of 30 to 70 nm and said second liner (10) of TiN has a thickness of 5 to 15 nm.

7. An integrated semiconductor structure comprising:
an integrated circuit substrate (1) having a main surface;
a dielectric layer (2) on said main surface;
a via (3) in said dielectric layer (2), said via (3) exposing a contact area (1a) of said integrated circuit substrate (1);
a Ti silicide region (5) formed in said contact area (1a);
a liner (10) of TiN on said dielectric layer (2) and said contact area (1a); and
a conductive layer (6′) which fills said via (3) and covers a periphery of said via (3) on said second liner (10) of TiN.
